(19) United States
(12) Patent Application Publication
(10) Pub. No.: US 2008/0204044 A1
(43) Pub. Date: Aug. 28, 2008

(54) Method for detecting islanding operation of a distributed generator

(75) Inventors: Srinivas Ponnaluri, Untersiggenthal (CH); Beat Ronner, Maisprach (CH)

Correspondence Address: BUCHANAN, INGERSOLL & ROONEY PC, POST OFFICE BOX 1404, ALEXANDRIA, VA, 22313-1404, US

(73) Assignee: ABB Schweiz AG, Baden (CH)

(21) Appl. No.: 12/076,397

(22) Filed: Mar. 18, 2008

Related U.S. Application Data
(63) Continuation of application No. PCT/CH2006/000494, filed on Sep. 14, 2006.

(30) Foreign Application Priority Data
Sep. 19, 2005 (EP) 05405545.4

(51) Int. Cl. G01R 27/04

(52) U.S. Cl. 324/647

(57) ABSTRACT

An exemplary method comprises the steps of introducing a reactive current reference square wave, detecting load voltage changes at every change in the reactive current reverence wave, and determining whether the detected load voltage changes exceed a predefined islanding detection threshold value, indicating a loss of mains and an islanding operation of the power generator. With the exemplary loss-of-mains detection, islanding can be detected within a shortest period of time, even if the local islands active and reactive load matches exactly the distributed generators active and reactive power generation. So even without a sudden voltage change, unintentional islanding can immediately be detected and control electronics can safely turn of the distributed power generator.

### RELATED APPLICATIONS

This application claims priority under 35 U.S.C. §119 to European Patent Application No. 05405545.4 filed in Europe on Sep. 19, 2005, and as a continuation application under 35 U.S.C. §120 to PCT/CH2006/000494 filed as an International Application on Sep. 14, 2006 designating the U.S., the entire contents of which are hereby incorporated by reference in their entireties.

### TECHNICAL FIELD

The present disclosure relates to the field of power electronics, and more particularly to a method for detecting the islanding operation of a distributed generator connected to a utility grid and to a device for detecting islanding operation of a distributed power generator.

### BACKGROUND INFORMATION

Distributed resources such as distributed power generators are used to feed additional active power into a utility grid close to electrical loads or to ensure standby power for critical loads when power from the grid is temporarily unavailable. Distributed generators are connected to the power grid with power electronic switches.

When one or more distributed resources become isolated from the rest of the power system and inadvertently continue to serve local island loads separately from the utility grid, the condition is known as “loss of mains” or “unintentional islanding”.

Upon having lost the stability provided by the utility grid, differences in active and reactive power of the local island load and the power generation of the distributed generator may lead to sudden large voltage changes. This usually causes the distributed generator protection device to act and trip immediately.

If, however, the active and reactive power of the local island load matches the active and reactive power generation, there will be no voltage jump that would trigger the protection device. Unless there is an alternative islanding detection, the distributed generator would continue to operate. Even though some of the distributed generators are designed to run in islanding, a number of potentially serious problems are associated with islanding:

Distributed-generation equipment such as a motor-generator set can become an isolated source of electricity during power outages on the grid, posing harm to utility personnel and equipment.

Customer equipment may be damaged by uncontrolled voltage and frequency excursions.

Utility equipment, such as surge arresters, may be damaged by over-voltages that occur during a shift neutral reference or resonance.

Utility personnel or the public may be harmed by the inadvertent energizing of the lines by the distributed resources.

It is therefore desirable to immediately react upon detection of an unintentional loss of mains. In order to address the above-mentioned safety concerns in distributed generation, Underwriters Laboratories Standard UL 1741 was developed. Standard UL 1741 requires tripping of the distributed generator within two seconds once the connection to the utility grid has been lost.

### BACKGROUND ART

In “Islanding Detection Method of Distributed Generation Units Connected to Power Distribution System”, J. E. Kim, J. S. Hwang, IEEE 2000, a method is proposed for distributed power generation based on synchronous generators. To detect islanding, the internal electromagnetic field of the generator is increased and the change in the reactive power flow and the load voltage are examined. As the internal impedance of the power generator is up to a few percent of the power generators rating, a one percent change in the generated voltage will produce a large change in reactive power when grid is present. Due to the utility grids stability, the load voltage is not affected. Once the connecting breaker is open there will be no significant change in reactive power and the load voltage will change in the same proportion as the internal voltage variation. Using this information the Loss of Mains is detected.

In “Performance of Inverter Interfaced Distributed Generation”. Simon R. Wall, IEEE 2001, a method is proposed where the frequency output of a phase locked loop (PLL) as shown in FIG. 3 is disturbed by adding an additional disturbance frequency. When the utility grid is present the load voltage is nearly unchanged. Increase in frequency will increase the phase angle of the inverter internal voltage. As the load voltage remains steady in presence of the utility grid voltage, the active and reactive power controllers will compensate the angle error. In case of an islanded network an increase in frequency will cause the internal voltage angle to advance. As the load impedance is significantly higher than the internal impedance of the power generator, the load voltage will follow the change in phase angle. This would not change the active and reactive powers significantly but the PLL will see a phase lead in the voltage and try to chase the same by increasing the frequency further. This process will go on until a rate of change of frequency-trip is activated or an over frequency-trip occurs.

In “An Improved Anti-Islanding Algorithm for Utility Interconnection of Multiple Distributed Fuel Cell Powered Generations”, CH. JERAPUTRA et al, IEEE 2005, an anti-islanding algorithm for utility interconnection of multiple distributed fuel cell powered generations (DFPG) is presented. While the power control algorithm continuously perturbs the reactive power supplied by the DFPG, the proposed algorithm calculates the cross-correlation index of a rate of change of the frequency deviation with respect to the reactive power to confirm islanding. If this index is above 50%, the algorithm further initiates the reactive power perturbation and continues to calculate the correlation index. If the index exceeds 80%, the occurrence of islanding can be confirmed. The proposed method is capable of detecting the occurrence of islanding in the presence of several DFPGs, which are independently operating.

### SUMMARY

A method for detecting islanding of a distributed power generator and a device for detecting islanding operation of a distributed power generator are disclosed.

A method for detecting islanding operation of a distributed resource is disclosed, said distributed resource having a local island load (Z_{Id}), comprising the steps of introducing a reactive reference wave current, detecting changes of the local island load voltage caused by the reactive reference wave current by measuring, sampling and storing the current load voltage values (u(t)) and by comparing the current load voltage values to previously measured, sampled and stored load voltage values (u(t−dt)), said load voltage changes being detected every time the reference wave current passes a threshold value, and determining whether the detected load voltage changes exceed a predefined islanding detection threshold value, indicating an islanding operation of the distributed resource.

A device for detecting islanding operation of a distributed resource is disclosed, comprising means for introducing a reactive current reference wave, means for detecting load voltage changes triggered by changes in reactive current reverence wave, said detecting means comprising means for measuring, sampling and storing the current load voltage values (u(t)) and means for comparing the current load voltage values to previously measured, sampled and stored load voltage values (u(t−dt)), and means for determining whether the detected load voltage changes exceed a predefined islanding detection threshold value, indicating an islanding operation of the power generator.

### BRIEF DESCRIPTION OF THE DRAWINGS

The exemplary method and device will be explained in more details on the bases of the drawings. The drawings are as follows:

FIG. 1 shows a circuit model in grid operation,

FIG. 2 shows a resonant circuit for anti-islanding test as defined by the standard UL 1741,

FIG. 3 shows an exemplary general phase locked loop (PLL),

FIG. 4 shows the reactive current reference generated for an exemplary loss-of-mains detection, and

FIG. 5 shows an exemplary logic for islanding detection.

### DETAILED DESCRIPTION

An exemplary method comprises the steps of introducing a reactive current reference wave, detecting load voltage changes caused by changes in the reactive current reverence wave, and determining whether the detected load voltage changes exceed a predefined islanding detection threshold value, indicating a loss of mains and an islanding operation of the power generator. When the grid is present the local island load voltage is same as the grid voltage. In case of grid disconnection, the local island load voltage is provided by the inverter or distributed generator.

The reactive current reference wave can be a square wave, a ramp wave, a sine wave or a trapezoidal wave. Load voltage samples are taken every time the reference current passes a threshold value or, in case of a square wave, when it changes its value.

A counter value can be incremented every time the detected load voltage changes exceed the predefined islanding detection threshold value, and the loss of mains can be detected if within a predefined period of time the increment of the counter value exceeds a predefined value. If the counter value is reset at the beginning of the predefined period of time, the loss of mains is detected if the counter value exceeds the predefined value at the end of the predefined period of time.

If the predefined islanding detection threshold value of the voltage is chosen to be at least approximately 50 percent of the impedance level, the reliability of islanding detection can be approved. For values substantially below 50 percent of the impedance level, there is a certain risk of false detection of islanding operation.

If the injected current used is a harmonic, it's frequency can be set below the LCL filter corner frequency of the inverter. Otherwise a substantial part of the injected current is filtered by the capacitor and only a small part reaches the utility grid.

With an exemplary loss-of-mains detection, islanding can be detected within a shortest period of time, even if the local islands active and reactive load matches exactly the distributed generators active and reactive power generation. So even without a sudden voltage change, unintentional islanding can immediately be detected and control electronics can safely turn of the distributed power generator.

As mentioned above, distributed generators generate and feed active power in to the utility grid and some of them also have the capability to run in island mode. However, it is important for safety reasons, that such power generation does not take place in an unintentional island. An unintentional island can be created because of opening of a breaker by maintenance personnel or by tripping of a far end breaker. Such a situation is schematically shown in FIG. 1. When the incoming breaker B_{g} is opened the power electronics based distributed generator DG, which is also often referred to as distributed resource (DR) or uninterruptible power supply (UPS), continues to supply the local island with power.

When the grid is present the local island load voltage is same as the grid voltage. In case of grid disconnection, the local island load voltage is provided by the inverter or distributed generator. If the local islands active and reactive load is significantly different from the distributed generators active and reactive power generation, then after opening of the incoming breaker this difference will create a large voltage change. The large change in voltage indicates as loss of mains. The distribute generator protection will act and safely open contactor B_{DR} within time. The distributed generator is disconnected and no further action is required.

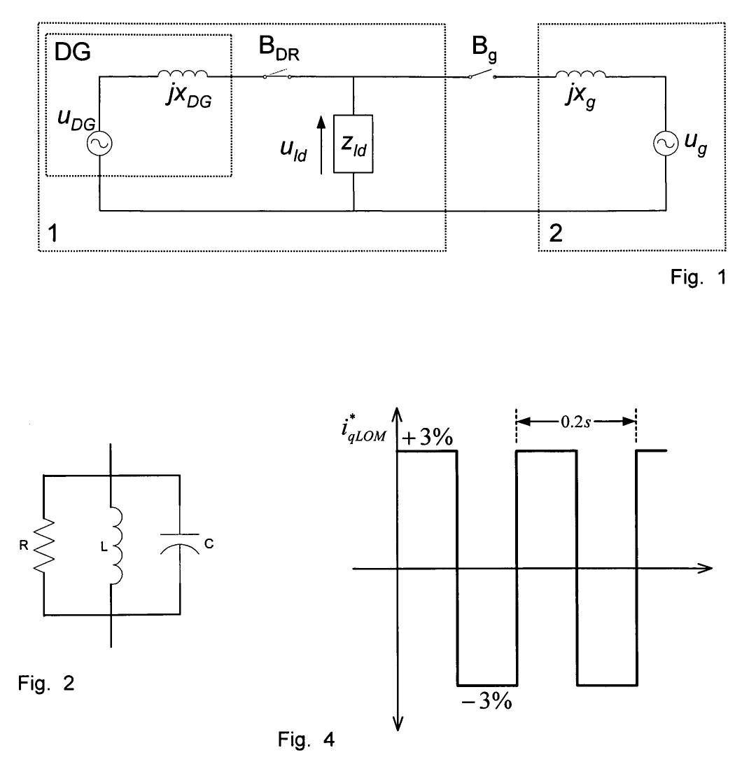

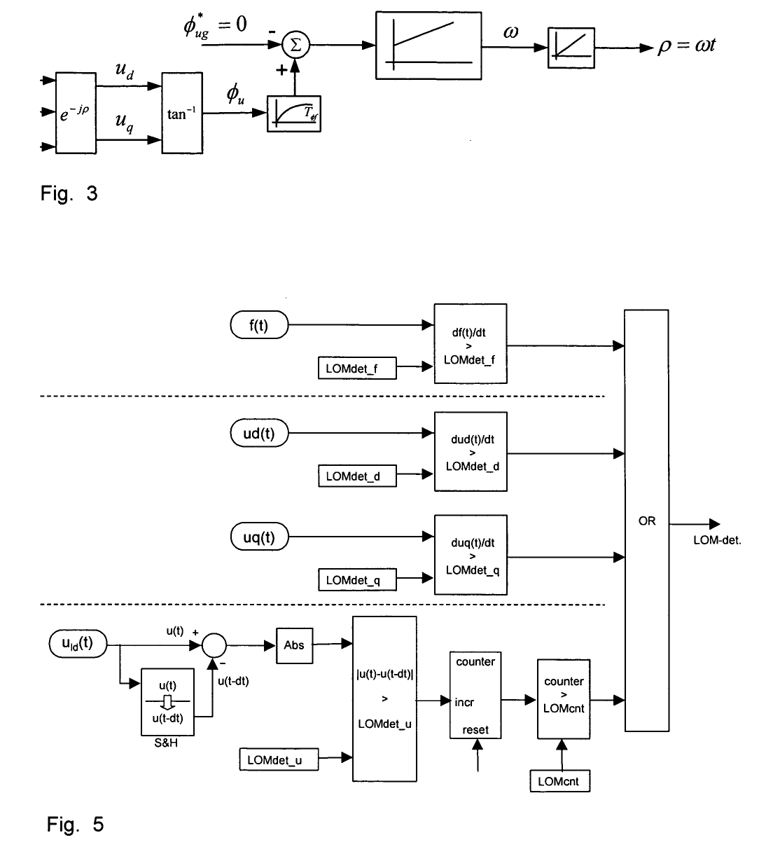

If, however, the local islands active and reactive load matches exactly the distributed generators active and reactive power generation, the control electronics will see no voltage jump and the distributed generator continues to operate. The UL 1741 standard specifies that the distributed generator must trip even under such a condition within two seconds. For test purposes a local island load Z_{Id} is connected to the distributed generator, as shown in FIG. 2. The parallel L and C of the load are tuned to the fundamental frequency of the network and split to match the reactive power generation of the distributed generator. The resistor is chosen to match the active power generation of the distributed generator. During the test the active and reactive power injected in to the network shall not vary more than ±3 percent of the rated kVA of the distributed generator, according to the UL 1741 test requirements. To test the exemplary loss-of-mains detection, the incoming breaker is opened. In order to pass the loss-of-mains detection test, the distributed generator has to trip within 2 seconds from the opening of the incoming breaker.

The exemplary loss-of-mains detection is based on injection of reactive current or power at fundamental or any other selected frequency. The injection levels are chosen to be within the UL 1741 standard limits of ±3 percent of the rated current.

In an exemplary embodiment of the disclosed loss-of-mains detection, a reactive current reference square wave as shown in FIG. 4 is generated at a frequency of 5 Hz with a magnitude of ±3 percent of the rated current. The frequency of the reactive current reference square wave was set to 5 Hz. Of course, the frequency can be set to another value above 5 Hz or even below, as long as there are a sufficient number of changes in the reference current during the 2 second period.

The reactive current injection has an impact on the load voltage u_{Id}. The load voltage is therefore monitored and changes corresponding to the current injection are detected. As long as the utility grid is present and thus provides stability, the change in load voltage due to the injected reactive current reference square wave is minimal.

But as soon as the utility grid is disconnected by opening the incoming breaker B_{g}, the load voltage changes significantly. The impedance Z_{Id} of the separated island load is several times higher than the total grid impedance.

In order to detect a loss of mains, the load voltage is sampled and stored every time a change in the reactive current reference square wave happens. The samples of the load voltage changes d and q axis voltages are held as shown in FIG. 5 and will be compared at the time of the next change in the reactive current reference square wave to the then current load voltage. The difference between the actual d and q axis voltages u(t) and the previously sampled and held values u(t−dt) is calculated. The absolute of the difference between the actual d and q axis voltages and their sampled and held values is then compared with an islanding detection threshold value LOMdet_u. If at any time the voltage change exceeds the islanding detection threshold value a loss of mains is detected. In order not to falsely detect a loss of mains if the comparator values exceeds the threshold value due to a disturbance in the still available utility grid the following safety measure can be implemented.

A counter is implemented to count the number of loss-of-mains detections within a specified period of time. Each time a loss of mains is detected, a counter value is incremented. Within the UL 1741 standard specified time of two seconds, the exemplary reactive current square wave has 20 edges, thus changes its value 20 times. This gives a possibility of voltage comparison and loss-of-mains detection of at least 19 times within the two second interval. At the end of the interval, if the counter has not gone above a predefined counter threshold value LOMcnt, e.g. above 10, it is assumed that there is no loss of mains and that disturbances in the utility grid voltage have caused voltage jumps. If the counter does go above the specified number, then a loss of mains is detected. The counter is reset at the beginning of every period of two seconds.

Instead of a square wave the reactive current reference injected can alternatively be a ramp wave, a sine wave or a trapezoidal wave. The reference wave can be used to trigger the sampling of the load voltage. A sample of the monitored voltage is taken each time the current wave passes a certain threshold value or when it changes from a positive to a negative value or vice-versa.

Assuming a linear load and an active power difference of ΔP and reactive power difference of ΔQ, the load voltage jump as a function of difference power when the utility grid is lost is given by,

(Δu_{d}+jΔu_{q})·(Δu_{d}+jΔu_{q})=(ΔP+jΔQ)·(R_{load}+jX_{load})

or

Δu_{d}²−Δu_{q}²=ΔPR_{load}−ΔQX_{load}

2Δu_{d}Δu_{q}=ΔPX_{load}+ΔQR_{load} (1)

Both d and q axis voltages u_{d} and u_{q} get disturbed in case of a loss of mains. This causes the voltage angle to suddenly change and therefore the PLL will change the frequency f. This in turn will decrease or increase the frequency depending on the impedance and change in powers.

The exemplary loss-of-mains detection can be used in combination with an additional detection of loss of mains based on df/dt and over-/under-voltage. The additional detections are also included in FIG. 5.

If the frequency or either or both of the active and/or reactive voltage changes faster than a given rate (LOMdet_f, LOMdet_d or LOMdet_q), this is an indication for loss of grid.

Both of these two additional detections can be used for fast loss-of-mains detection whenever the local load does not match the power generation. The output of each detection branch is monitored and loss of mains is detected by the system whenever at least one of the paralleled detection systems produces a positive loss-of-mains detection signal.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

B_{DR} breaker distributed resource
B_{g} incoming breaker
DG Distributed generator
Z_{Id} Local island load
LOMdet_d, LOMdet_q, Islanding detection threshold values
LOMdet_u, LOMdet_f
LOMcnt Islanding detection counter threshold
1 Local island
2 Utility grid

What is claimed is:

1. Method for detecting islanding operation of a distributed resource, said distributed resource having a local island load (Z_{Id}), comprising the steps of
introducing a reactive reference wave current,
detecting changes of the local island load voltage caused by the reactive reference wave current by measuring, sampling and storing the current load voltage values (u(t)) and by comparing the current load voltage values to previously measured, sampled and stored load voltage values (u(t−dt)), said load voltage changes being detected every time the reference wave current passes a threshold value, and
determining whether the detected load voltage changes exceed a predefined islanding detection threshold value, indicating an islanding operation of the distributed resource.

2. Method of claim 1, wherein
the reactive reference wave current is any of the following: a square wave, a ramp wave, a sine wave or a trapezoidal wave.

3. Method of claim 1, wherein
the reactive reference wave current introduced is a square wave, and
the load voltage changes are detected every time the reference current changes its value.

4. Method of claim 1, further comprising the step of
incrementing a counter value every time the detected load voltage changes exceed the predefined islanding detection threshold value, and
detecting an islanding operation if within a predefined period of time the increment of the counter value exceeds a predefined counter threshold value (LOMcnt).

5. Method of claim 4, wherein
the counter value is reset at the beginning of the predefined period of time, and
the islanding operation is detected if the counter value exceeds the predefined counter threshold value (LOMcnt) at the end of the predefined period of time.

6. Method of claim 1, comprising
the change of load voltage frequency (df(t)/dt) is detected, and
the islanding operation is detected if the change rate of frequency exceeds a predefined rate (LOMdet_f).

7. Method of claim 1, comprising
the change in active and/or reactive load voltage (du_{d}(t)/dt, du_{q}(t)/dt) are detected, and
the islanding operation is detected if the load voltage change rate exceeds a predefined rate (LOMdet_d, LOMdet_q).

8. Device for detecting islanding operation of a distributed resource, comprising
means for introducing a reactive current reference wave,
means for detecting load voltage changes triggered by changes in reactive current reverence wave, said detecting means comprising means for measuring, sampling and storing the current load voltage values (u(t)) and means for comparing the current load voltage values to previously measured, sampled and stored load voltage values (u(t−dt)), and
means for determining whether the detected load voltage changes exceed a predefined islanding detection threshold value, indicating an islanding operation of the power generator.

9. Device of claim 7, further comprising
a counter, the value of which can be incremented every time the detected load voltage changes exceed the predefined islanding detection threshold value, and
means for detecting an islanding operation if within a predefined period of time the increment of the counter value or the counter value itself exceeds a predefined value.

10. Method of claim 2, wherein
the reactive reference wave current introduced is a square wave, and
the load voltage changes are detected every time the reference current changes its value.

11. Method of claim 3, comprising the steps of
incrementing a counter value every time the detected load voltage changes exceed the predefined islanding detection threshold value, and
detecting an islanding operation if within a predefined period of time the increment of the counter value exceeds a predefined counter threshold value (LOMcnt).

12. Method of claim 5, comprising
the change of load voltage frequency (df(t)/dt) is detected, and
the islanding operation is detected if the change rate of frequency exceeds a predefined rate (LOMdet_f.

13. Method of claim 6, comprising
the change in active and/or reactive load voltage (du_{d}(t)/dt, du_{q}(t)/dt) are detected, and
the islanding operation is detected if the load voltage change rate exceeds a predefined rate (LOMdet_d, LOMdet_q).
